(19) United States
(12) Patent Application Publication
(10) Pub. No.: US 2023/0309328 A1
(43) Pub. Date: Sep. 28, 2023

(54) LIQUID CRYSTALLINE GEL-BASED PHOTOVOLTAIC DEVICES

(71) Applicant: M and N Technology LLC, Red Bank, NJ (US)

(72) Inventors: Gene C. KOCH, Corvallis, OR (US); John N. MAGNO, Newton, PA (US)

(21) Appl. No.: 18/046,465

(22) Filed: Oct. 13, 2022

Related U.S. Application Data
(60) Provisional application No. 63/255,052, filed on Oct. 13, 2021.

(51) Int. Cl. H10K 30/50; C08F 116/12; C08F 122/26; H10K 30/20

(52) U.S. Cl. CPC H10K 30/50; C08F 116/12; C08F 122/26; H10K 30/20; C08F 2810/20

(57) ABSTRACT

A photovoltaic device including an interconnecting liquid crystalline polymer network is described. The interconnecting liquid crystalline polymer network is formed using a process including polymerizing a mixture of components with linear or lathe-shaped molecules terminated with two or more crosslinking groups and one or more non-polymerizable liquid crystalline components. The linear or lathe-shaped molecules terminated with two or more crosslinking groups include flexible spacers connecting chromophoric molecular cores to each of the crosslinking groups. The components with linear or lathe-shaped molecules terminated with two or more crosslinking groups make up between twenty and forty percent of said mixture. At least two of the components with linear or lathe-shaped molecules have the same chromophoric core and each of these components make up ten percent or less of said mixture. Subsequently one or more non-polymerizable liquid crystalline components are removed from the polymerized mixture and then replaced with a polymerizable material.

### CROSS-REFERENCE TO RELATED APPLICATIONS

This application claims priority to and benefit of U.S. Provisional Patent Application No. 63/255,052, filed Oct. 13, 2021, which is incorporated by reference herein in its entirety.

### BACKGROUND

In a patent (U.S. Pat. No. 7,820,907) and a published paper (Adv. Mater. 2006, 18, 1754-1758) (the “O'Neill Paper”) O'Neill, Kelly and co-workers describe photovoltaic devices that utilize a fabrication process utilizing the formation of nematic liquid crystal polymer gels formed by photopolymerization of mixtures of liquid crystalline monomers with a non-polymerizable liquid crystals. Both U.S. Pat. No. 7,820,907 and the O'Neill Paper are herein incorporated by reference in their entirety. For instance, a mixture of compounds 1 (33%) and 2 (67%) shown below was coated (e.g. by spin coating) on to a PEDOT:PSS coated ITO substrate and then compound 1 was photocrosslinked by exposure to UV radiation.

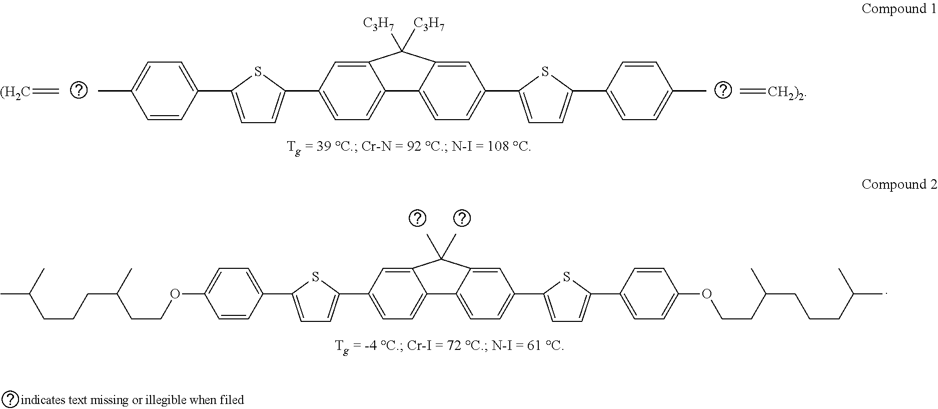

The crosslinking of compound 1 proceeded through the 1,4-pentadien-3-yl at both ends of the molecule. Note that compound 1 is drawn as shown in the O'Neill and Kelly paper described above, but it appears that was an error in that paper: the 1,4-pentadien-3-yl structure at the left end of the molecular formula was drawn wrong and should be the same as that at the right end of the molecular formula. It can be seen from the melting points (crystal to nematic and crystal to isotropic) and also the nematic to isotropic transition temperatures that the mixture was unlikely to have a stable nematic phase at room temperature. However, as is often the case with mixtures of this type, the film obtained was a nematic glass and the film resulting from polymerization was a polymer gel with nematic molecular order.

Next the non-crosslinked compound 2 was washed out of the gel with a suitable solvent (e.g. chloroform) and the resultant aerogel was dried. The air-filled voids had widths measured in the tens of angstroms. Next a solution of non-liquid crystalline compound 3 was spun onto the aerogel.

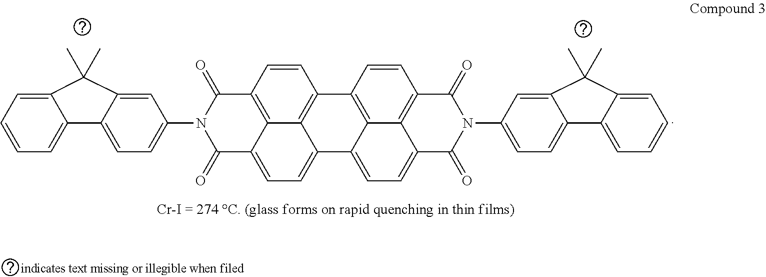 [SMILES: CC1(C)c2ccccc2-c2ccc(N3C(=O)c4ccc5c6ccc7c8c(ccc(c9ccc(c4c59)C3=O)c86)C(=O)N(c3ccc4c(c3)C(C)(C)c3ccccc3-4)C7=O)cc21]

Once the spin coating solvent had evaporated it was found that the glassy compound 3 material had penetrated into and filled in the voids in the aerogel consisting of compound 1. An LiF/aluminum cathode was fabricated over the layer of compound 3. The contact surfaces between the compound 1 and compound 3 materials provided a bulk-distributed heterojunction that can produce photoinduced current upon illumination with light. The photovoltaic device produced in this way was found to have five times the energy conversion efficiency of a device produced with a planar interface between polymerized compound 1 and a glassy film of compound 3.

The power conversion efficiency of the bulk distributed heterojunction device described above was low, 0.6%. This likely, in part, due to the low extinction coefficient of the fluorene-based and perylenediimide-based films coupled with 110 nm total thickness of the active organic layers. In addition, the transition moments of the compound 3 molecules will be randomly oriented due to the amorphous nature of the material and thus molecules with transition moments parallel to the propagation direction of incident light will not interact to form excitons. The liquid crystalline molecular cores of the polymerized compound 1 will be randomly oriented on a macroscopic basis aligned locally so as to interact with only polarization of incoming light allowing the other polarization to pass through unabsorbed.

### BRIEF SUMMARY

Embodiments include a photovoltaic device including an interconnecting liquid crystalline polymer network, wherein the interconnecting liquid crystalline polymer network is formed using a process including one step that includes polymerizing a mixture of components with linear or lathe-shaped molecules terminated with two or more crosslinking groups in the presence of one or more non-polymerizable liquid crystalline components. The linear or lathe-shaped molecules terminated with two or more crosslinking groups include flexible spacers connecting chromophoric molecular cores to each of the crosslinking groups, the components with linear or lathe-shaped molecules terminated with two or more crosslinking groups make up between twenty and forty percent of said mixture, and at least two of the components with linear or lathe-shaped molecules have the same chromophoric core and each of these components make up ten percent or less of said mixture. One or more subsequent steps in forming the interconnecting liquid crystalline polymer network are removal of the one or more non-polymerizable liquid crystalline components from the polymerized mixture and then replacing the one or more non-polymerizable liquid crystalline components with a polymerizable material.

Embodiments further include a photovoltaic device described above wherein at least one of the chromophoric molecular cores is electron accepting.

Embodiments further include a photovoltaic device described above wherein the one or more non-polymerizable liquid crystalline components are electron donating.

Embodiments further include a photovoltaic device described above wherein at least one of the chromophoric molecular cores is electron donating.

Embodiments further include a photovoltaic device described above wherein the one or more non-polymerizable liquid crystalline components are electron accepting.

Embodiments further include a photovoltaic device described above wherein the photovoltaic device includes a reflector.

Embodiments further include a photovoltaic device described above wherein the photovoltaic device is built up on a substrate.

Embodiments further include a photovoltaic device described above wherein the substrate is transparent.

Embodiments further include a photovoltaic device described above wherein the substrate is glass.

Embodiments further include a photovoltaic device described above wherein the substrate is plastic.

Embodiments further include a photovoltaic device described above wherein the polymerizable mixture used to form the interconnecting liquid crystalline polymer network is solvent cast on an anode that was previously coated onto a substrate.

Embodiments further include a photovoltaic device described above wherein the polymerizable mixture used to form the interconnecting liquid crystalline polymer network is solvent cast on a cathode that was previously coated onto a substrate.

Embodiments further include a photovoltaic device described above wherein one or more of the one or more non-polymerizable liquid crystalline components have crystal to nematic phase transitions.

Embodiments further include a photovoltaic device described above wherein the interconnecting liquid crystalline polymer network has nematic liquid crystalline order.

Embodiments further include a photovoltaic device described above wherein at least one of the components with linear or lathe-shaped molecules terminated with two or more crosslinking groups has a crystal to nematic phase transition.

Embodiments further include a photovoltaic device described above wherein at least one of the flexible spacers connecting chromophoric molecular cores to each of the crosslinking groups is a n-alkyl or branched alkyl group.

Embodiments further include a photovoltaic device described above wherein at least one of the at least one of the flexible spacers that is a linear or branched alkyl group has at least one of its methylene groups replaced by a an oxygen, sulfur atom, carboxylate group, or carbonato group.

Embodiments further include a photovoltaic device described above wherein the two or more crosslinking groups is selected from the group consisting of methacrylato, vinyloxy, phthalimido, acrylato, and 1,4-pentadien-3-yl groups.

Embodiments further include a photovoltaic device described above wherein the polymerizable material that replaces the one or more non-polymerizable liquid crystalline components contains one or more materials that include chromophoric cores.

Embodiments further include a photovoltaic device described above wherein at least one of the chromophoric cores is electron accepting.

Embodiments further include a photovoltaic device described above wherein at least one of the chromophoric cores is electron donating.

Embodiments further include a photovoltaic device described above wherein the polymerizable material that replaces the one or more non-polymerizable liquid crystalline components contains one or more liquid crystalline components.

Embodiments further include a photovoltaic device described above wherein the polymerizable material that replaces the one or more non-polymerizable liquid crystalline components contains one or more components that have crystal to nematic phase transitions.

Embodiments further include a photovoltaic device described above wherein the polymerization that forms the interconnecting liquid crystalline polymer network is photopolymerization.

Embodiments further include a photovoltaic device described above wherein the photopolymerization is UV photopolymerization.

Embodiments further include a photovoltaic device described above wherein the polymerizable material that replaces the one or more non-polymerizable components is UV polymerizable.

Embodiments further include a photovoltaic device described above wherein the interconnecting liquid crystalline polymer network has chiral nematic liquid crystalline order.

Embodiments further include a photovoltaic device described above wherein one or more of the one or more non-polymerizable liquid crystalline components has a crystal to chiral nematic phase transition.

Embodiments further include a photovoltaic device described above wherein the interconnecting liquid crystalline polymer network has chiral nematic liquid crystalline order and wherein the polymerizable material that replaces the one or more non-polymerizable liquid crystalline components polymerizes to polymer with a chiral nematic structure.

Embodiments further include a photovoltaic device described above wherein the interconnecting liquid crystalline polymer network and the polymer that is formed from the material that replaces the one or more non-polymerizable components both have chiral nematic structures that both have the same helical pitch.

Embodiments further include a photovoltaic device described above wherein the interconnecting liquid crystalline polymer network has nematic liquid crystalline order and the polymer formed from the polymerizable material that replaces the one or more non-polymerizable liquid crystalline components has nematic liquid crystalline order and the polymer included by the interconnecting liquid crystalline polymer network and polymer formed from the polymerizable material that replaces the one or more non-polymerizable liquid crystalline components both have the same ordinary and extraordinary refractive indices.

Embodiments further include a photovoltaic device described above wherein the interconnecting liquid crystalline polymer network is doped with an n-dopant.

Embodiments further include a photovoltaic device described above wherein the interconnecting liquid crystalline polymer network is doped with an p-dopant.

Embodiments further include a photovoltaic device described above wherein at least one other component among the components with linear or lathe-shaped molecules has a different chromophoric core from the two components that have the same chromophoric core, each of which make up ten percent or less of said mixture.

Embodiments further include a photovoltaic device described above wherein the at least one other component is electron donating.

Embodiments further include a photovoltaic device described above wherein the at least one other component is electron accepting.

### DETAILED DESCRIPTION

Since the application leading to U.S. Pat. No. 7,820,907, discussed above, was published in 2007, considerable progress has been made in producing both electron acceptor and donor materials with spectrally broad and intense light absorption. However, there are issues with many of these materials in terms of their use in liquid crystalline gel devices. Many of these materials have molecular structures that would not easily lend themselves to molecular structural changes that would result in the materials having nematic phase behavior. Even if such structural changes were synthetically facile, another problem is that since nearly all these new materials have quite elevated melting points. This implies high enthalpies of fusion and as a result low solubilities in a liquid crystal mixture.

A goal of the design of the liquid crystalline gel photovoltaic devices is very high light absorption in the photovoltaic materials leading to near complete light absorption in a thin (e.g. under 200 nm.) layer. For this reason, one would like to have the polymer material comprised by the aerogel be completely or largely composed of the electron accepting or donating component. That is to say, one would like the photocrosslinkable component in the liquid crystalline mixture coated onto the photovoltaic device substrate to consist nearly entirely of the active photovoltaic material and not an inactive liquid crystalline solvent.

An example of electron acceptor that is used in state-of-the-art OPV devices is the compound ITIC whose molecular structure is shown below. This is a material with very strong light absorption between 600 nm and 800 nm.

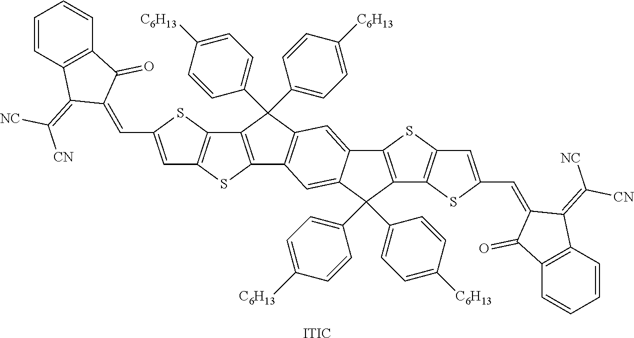

This compound melts at a temperature in excess of 200° C. and is not liquid crystalline. The molecules of this material, like many electron accepting or donating materials, are lathe or rod-like in shape. The general strategy for incorporating materials having these properties into liquid crystalline gel photovoltaic devices begins with attaching at least two flexible spacer chains to the ends of each of their chromophoric molecular cores approximately parallel to their long molecular axes and then attaching crosslinking groups to the ends of the flexible spacer chains. An example of this sort of structure is depicted below.

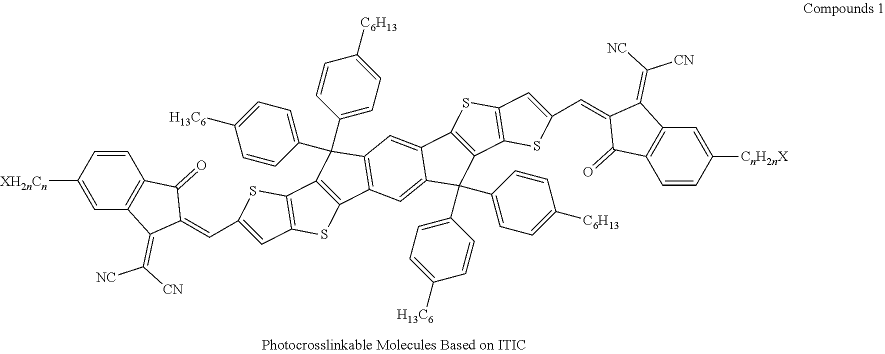

In the above structure n is an integer between 3 and 14, preferably between 5 and 12, X is a crosslinking group such as methacrylato, vinyloxy, phthalimido, acrylato or 1,4-pentadien-3-yl groups. Carbons in the flexible spacer chains may be replaced by heteroatoms such as oxygen or sulfur atoms or may be replaced with carboxylate or carbonato groups. The CₙH₂ₙ flexible spacer chains may comprise n-alkyl groups or branched alkyl groups.

The work by the Hull group that resulted in patent U.S. Pat. No. 7,820,907 established that the optimum concentration of photocrosslinkable components in the starting material used to form an aerogel with the desired properties is in the range of 20 to 40%. The low solubility (less than 10% and often less than 5%) of a single component with general formula above does not allow the dissolution of that amount of a photocrosslinkable material with that molecular formula shown above. The strategy used is to mix multiple materials with the general formula above into the non-crosslinkable liquid crystalline host. If sufficient individual compounds with the above formula are mixed with the host the desired concentration may be reached. The surprising and very useful result of this strategy is that once a liquid crystalline film of the 30 to 40% solution of material with the above formula in a liquid crystalline solvent is coated onto an electrode on top of a transparent, e.g. glass or plastic, substrate and photocrosslinked (for example, by UV light exposure) and then the non-crosslinkable liquid crystalline solvent is washed out yielding an aerogel, the photocrosslinked polymer comprised by the aerogel retains liquid crystalline order even though it is formed from monomeric components that are non-liquid crystalline. Thus, the advantages, such as increased charge carrier mobility, that are conferred by liquid crystalline molecular order are maintained in materials that would otherwise not be liquid crystalline.

An issue with this approach to producing liquid crystalline gel photovoltaic devices is that the presence of non-liquid crystalline components in a liquid crystalline mixture lowers the temperature of the liquid crystal to isotropic liquid transition. There are two strategies to ameliorate this. First, non-crosslinkable liquid crystals with longer molecules that have higher liquid crystal to isotropic transition temperatures can used to formulate the non-crosslinkable liquid crystal solvent. For instance, in U.S. Pat. No. 7,820,907 the non-crosslinkable liquid crystal solvent consisted of the single component:

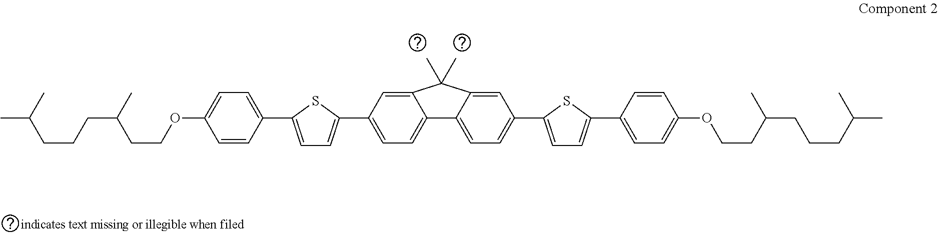 [SMILES: CC(C)CCCC(C)CCOc1ccc(-c2ccc(-c3ccc4c(c3)C(C)(C)c3cc(-c5ccc(-c6ccc(OCCC(C)CCCC(C)C)cc6)s5)ccc3-4)s2)cc1]

with a liquid crystal to isotropic transition at 61° C. A liquid crystalline material with a longer molecular structure:

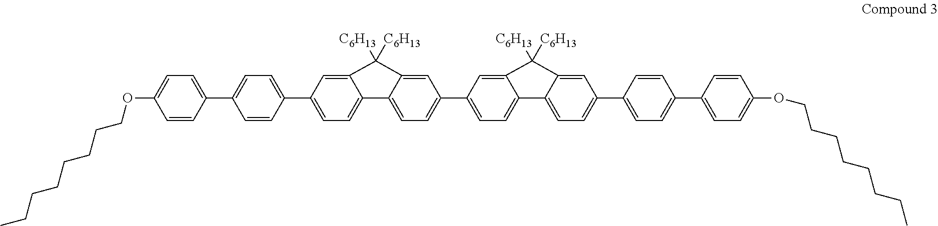

with a nematic to isotropic transition temperature of 250° C. and one or more similar materials may be mixed with component 2 to raise the nematic to isotropic transition temperature.

The second strategy to ameliorate the problem is to mix one or more crosslinkable liquid crystalline materials, preferably electron accepting materials, with the solution of ITIC in the non-crosslinkable solvent to increase the stability of the liquid crystalline phase. A typical liquid crystal monomer of this type is:

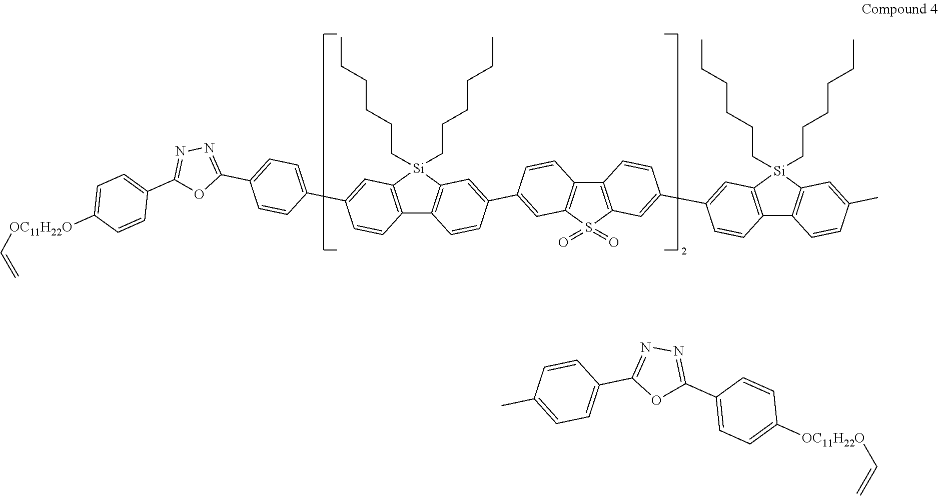

Once the aerogel comprising an electron accepting liquid crystalline polymer formed from monomers like compound 1 is produced on top of the cathode layer of a photovoltaic device, a solution comprising photocrosslinkable electron donating materials preferably liquid crystalline materials may be coated over the aerogel. The electron accepting materials intercalate into the aerogel structure replacing the non-crosslinkable liquid crystalline solvent that was formerly there. If the intercalated material is liquid crystalline, its liquid crystalline phase will be aligned with long molecular axes parallel to the long molecular axes of the liquid crystalline material that composes the aerogel. The intercalated material may then be crosslinked, for instance by UV exposure, yielding a solid polymeric assembly comprising a p-n junction with extremely high surface area. As an example, DR3TSBD is a donor material commonly used in OPV devices. It may be derivatized attaching at least two flexible spacer chains to the ends of each of its chromophoric molecular cores approximately parallel to their long molecular axes and then attaching crosslinking groups to the ends of the flexible spacer chains to produce the photocrosslinkable compound 5.

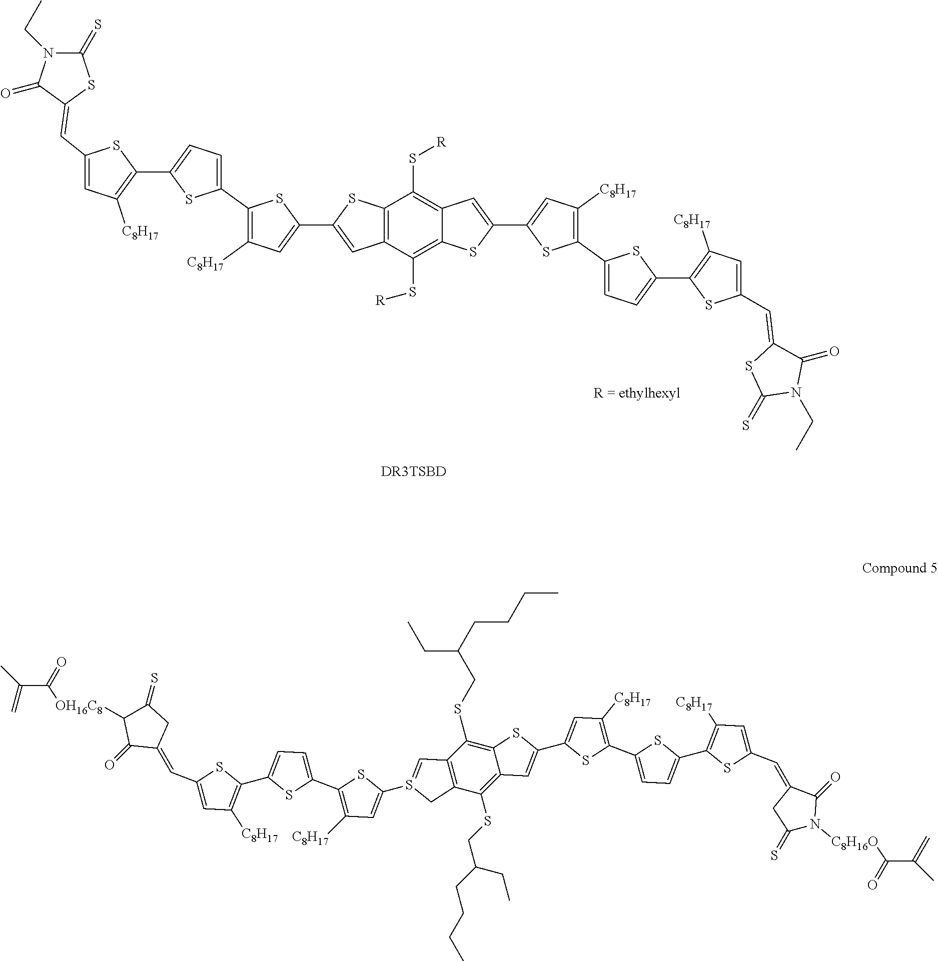

This material is not a liquid crystal but is roughly linear and it, and possibly its homologues, may be dissolved in crosslinkable, electron donating liquid crystalline host, for instance, compound 6 below. A solution of this mixture may be coated onto the electron accepting, liquid crystalline compound 5 aerogel described above.

In the organic photovoltaic (OPV) devices described above, the electron accepting material is coated down first and then after it is photocrosslinked, an electron donating material is coated on top. This layer stack is suitable to be built up on a cathode in the fabrication of an inverted OPV panel structure. In most cases the inverted devices described above will be built up on a suitable substrate such as glass or plastic topped with a reflective metallic cathode. Light then enters the device through a transparent anode that is formed on top of the organic material layers. The presence of a reflector allows a second pass of light through the organic layers minimizing the thickness of organic materials required to absorb all the light. If a reflective cathode is not used a reflector may be added to the device structure, for instance, on either the inner or outer surfaces of the substrate.

A non-inverted OPV panel structure may be formed by first coating a solution of compound 5 and the photocrosslinkable liquid crystalline compound 6 in a non-photocrosslinkable liquid

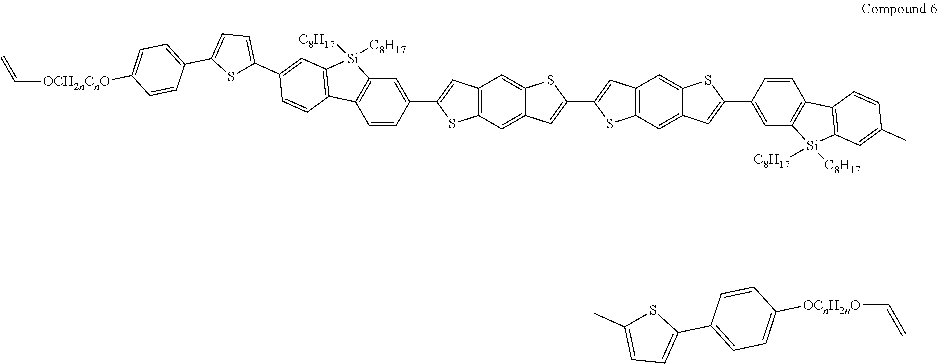

crystalline solvent comprising multiple compounds 7 mixed with multiple compounds 8 on top of an anode layer of a photovoltaic device.

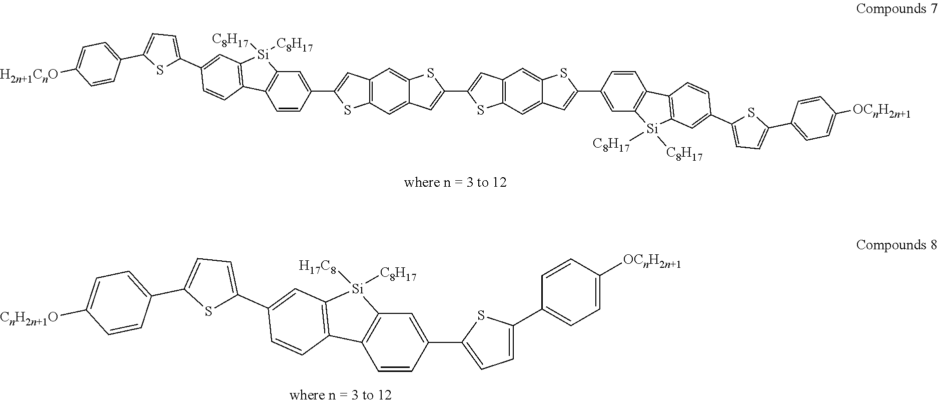

The strategy of using multiple homologues of an insufficiently soluble, photocrosslinkable acceptor or donor material to achieve an acceptable combined concentration in a liquid crystalline aerogel that can be converted into a photovoltaic device can be extended from non-liquid crystalline to liquid crystalline materials. As an example, the compound with the formula

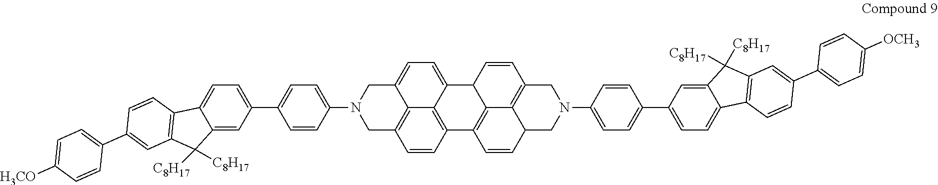

was developed as an electron acceptor by the Hull group (Lei, et al., Proc. of SPIE 7052, 705214) and has a crystal to nematic transition temperature of 285° C. and a nematic to isotropic transition in excess of 300° C. Liquid crystalline compounds based on this structure can be produced having the formula:

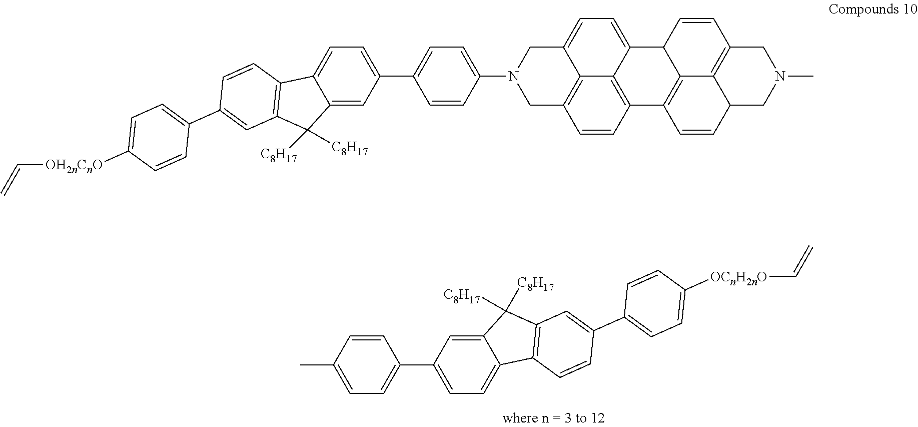

Many of these materials may have thermodynamically stable or monotropic liquid crystalline phases, but they will also have elevated melting points and low solubility. Multiple compound 10 materials may be mixed and then dissolved in a non-crosslinkable liquid crystalline host mixture to achieve a solution with a sufficient concentration of compound 10 material components. The resulting mixture may then be dissolved in a coating solvent and coated onto a substrate to begin the process of producing a liquid crystalline gel-based OPV device.

In the same paper the Hull group also reported the preparation of compound 11 below:

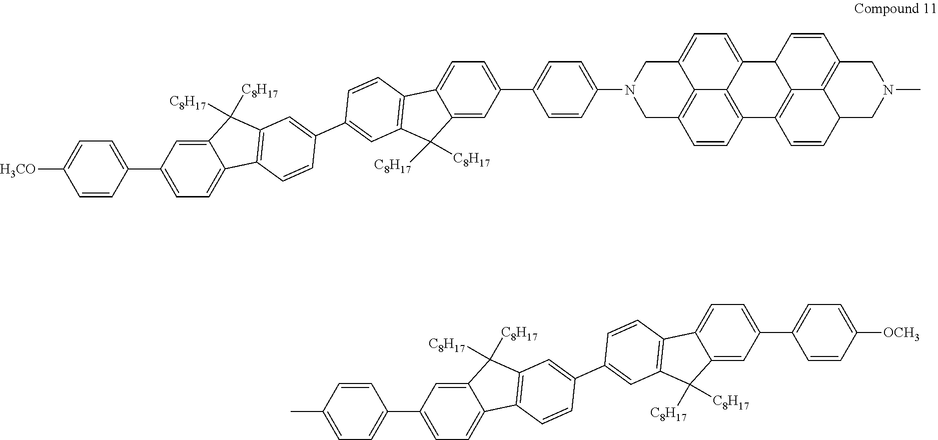

This material has a monotropic crystal to smectic transition at 183° C. and crystal to nematic transition temperature at 229° C. Liquid crystalline compounds based on this structure can be produced having the formula:

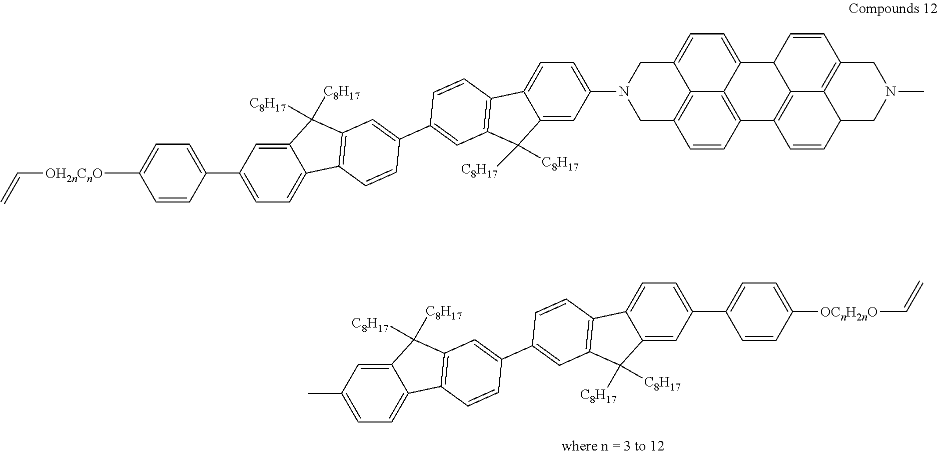

Many of these materials may also have thermodynamically stable or monotropic liquid crystalline phases, but they will also have elevated melting points and low solubility. Multiple compound 12 materials may be mixed together and then dissolved in a non-crosslinkable liquid crystalline host mixture to achieve a solution with a sufficient concentration of compound 10 material components. The resulting mixture may then be dissolved in a coating solvent and coated onto a substrate to begin the process of producing a liquid crystalline gel-based OPV device.

In all the materials discussed above flexible end chains with formula —OH₂ₙCₙO— the carbon atoms in the flexible end chains may be replaced by heteroatoms such as oxygen or sulfur atoms or be replaced with carboxylate or carbonato groups. In addition, in the same materials the crosslinking groups at the ends of the flexible spacers may be any suitable crosslinking group including methacrylato, vinyloxy, phthalimido, acrylato or 1,4-pentadien-3-yl groups.

Non-inverted OPV panel structures may be built up on anodes situated atop suitable substrates such as plastic or glass. The substrate/anode assembly may also comprise a reflector used direct incident light into a second pass through organic OPV materials. However, quite often the cathode formed on top of the organic materials will be a reflective metal. If this is the case light may be directed into the organic materials through a transparent substrate/anode assembly. If neither the substrate/anode assembly nor cathode is reflective a suitable reflector may be added to the device external to these layers.

In the above-described method of producing OPV devices utilizing liquid crystalline materials, after the non-crosslinkable liquid crystal components have been washed from the polymerized liquid crystalline material in the gel, some residual non-crosslinkable material may be left in the aerogel. In order to maximize the area of the heterojunction, it may be desirable that the non-crosslinkable liquid crystalline host components used be electron donating if the aerogel material is electron accepting or that the non-crosslinkable liquid crystalline host components used be electron accepting if the aerogel material is electron donating.

Currently a common method of producing bulk heterojunction OPV devices relies on the phase separation electron donor and electron acceptor polymers when films are cast from solvent solutions containing both polymers. The phase separation produces nano-composite films in which there are interpenetrating networks of electron donor material and electron acceptor material. This process is influenced by many process variables that are difficult to precisely control. By contrast, several liquid crystalline monomer components of the type described here may be copolymerized to produce a polymer which has uniform composition even on a nanoscale. When non-polymerizable liquid crystalline components are added to the polymerizable liquid crystal components in the solvent casting solution, the polymerization that follows film formation tends to segregate the polymer formed from the non-polymerizable material forming a gel. However, the polymerizable components still tend to remain uniformly distributed throughout out the polymer matrix. This confers a number of advantages. For instance, if an electron acceptor matrix is being formed a number of electron accepting liquid crystalline components or at least components alignable by liquid crystals all chosen to have different spectral light absorption bands may be copolymerized to form a polymer matrix that has broad spectral absorption. For example, multiple compounds 1 and compounds 10 from above may be mixed with non-polymerizable liquid crystal components and then may be dissolved in a solvent and cast in the first step of forming a gel-based-OPV. Similarly multi-component gel films may be produced from mixtures of photocrosslinkable electron donating materials with differing spectral absorption bands.

Another potential advantage is that liquid crystalline electron donating and electron accepting materials may be combined in the same polymer matrix. This may be useful in forming double heterojunction liquid crystalline gel-based photovoltaic devices. Also, the ability to use multiple components in mixture formulation allows the liquid crystal monomer mixture used to the produce the polymer matrix in the aerogel film and the liquid monomer mixture that is intercalated into the aerogel to form the p-n junction to each be blended so that the ordinary and extraordinary refractive indices of the electron donating and electron accepting polymers match across the interfaces between them. This, in turn, ensures that light is not reflected or scattered at these interfaces.

Yet a further advantage is that photopolymerizable p or n dopants may be added as components in the polymerization of the liquid crystal components used to form the liquid crystalline gel resulting in increased charge carrier mobilities in the resulting OPV devices.

The liquid crystalline gel OPV devices produced by the O'Neill and Kelly group (Adv. Mater. 2006, 18, 1754-1758) utilized unaligned nematic liquid crystalline films. When nematic liquid crystal films are unaligned, they adopt structures that are observed to show Schlieren textures under a polarizing microscope. These are molecular assemblies in which the nematic molecules are locally aligned with each other on a microscopic scale, but in which the direction of molecular alignment varies as one traverses across the liquid crystalline film. As a result, the alignment of molecules is random on a macroscopic scale but uniform on a nanoscopic scale. Optically this means that at any point across the surface of the liquid crystalline film only one polarization of incident light can be strongly absorbed by material in the nematic film. The efficiency of the OPV device could be nearly doubled if the light absorbing molecules encountered by incident light were oriented in all directions in the plane of the device.

The crosslinked molecular units in the polymer aerogel matrix used to produce the liquid crystalline gel-based photovoltaic devices may be uniformly aligned if the cast liquid crystal monomer containing film is uniformly aligned in a direction parallel to the plane of the device prior to crosslinking. This can be accomplished by solvent casting the film produced from solution containing the liquid crystalline components upon the surface of a layer of charge carrier transporting, liquid crystal alignment film that was previously formed on the surface of the substrate. Two types of charge carrier transporting liquid crystal alignment film that may be used are uniformly rubbed PEDOT-PSS polymer and the charge carrier transporting liquid crystal photoalignment films described in U.S. Pat. No. 10,707,426.

Uniform alignment of the crosslinked molecular units in the polymer aerogel matrix does not alone allow production of a film that absorbs all polarizations of light in the aerogel polymer matrix. What is needed to allow complete light absorption is that the liquid crystal polymer in the aerogel is a chiral nematic liquid crystalline polymer. Uniformly, homogenously aligned films of chiral nematic materials adopt a helical structure in which the liquid crystal molecules are parallel to the plane of the film and in which the direction of the long axes of the molecules rotates as one moves up through the thickness of the film. The result is that the light absorbing molecules in the aerogel are oriented so as to absorb light of all plane polarizations.

In order to fabricate the liquid crystalline gel-based photovoltaic devices using chiral nematic materials, a solution of non-crosslinkable chiral nematic compounds, photocrosslinkable electron accepting or electron accepting materials (these materials may be nematic liquid crystalline and/or may merely have roughly linearly molecular shapes), and optionally other photocrosslinkable nematic liquid crystalline materials are solvent cast as a film on an electrode substrate previously coated with a layer of a charge carrier transporting liquid crystal alignment film. None, some or all the photocrosslinkable components in the solvent casting solution may be chiral themselves so long as the desired helical pitch is achieved in the resulting polymer. Next the resulting chiral liquid crystalline film is crosslinked, preferably by exposure to UV light. The crosslinked film is then washed with a solvent that removes the molecules of non-crosslinkable material from the film and then dried yielding the aerogel film. Then if the aerogel contains electron accepting material a solution of electron donating polymerizable monomer is solvent cast onto the aerogel with electron donating material's molecules intercalating into the pores of the aerogel. If the aerogel contains electron donating material, the solvent cast monomer will be electron accepting. In each case, once the film has dried the overcoated intercalating material is crosslinked, preferably by UV exposure. It is preferred that the intercalating material be liquid crystalline and most preferred that it be a chiral nematic material with same helical pitch as the chiral nematic liquid crystalline material comprised by the aerogel.

As was the case with the non-chiral liquid crystalline polymers described previously for use in forming aerogels, crosslinkable non-liquid crystalline materials with linear molecular structures (for instance compounds 1, compound 5, and compound 10) may be utilized in the chiral nematic mixtures used to form the aerogel structures so long as they are aligned yielding nematic liquid crystalline order in the resulting solvent cast chiral nematic liquid crystalline film.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

1. A photovoltaic device comprising an interconnecting liquid crystalline polymer network,
wherein the interconnecting liquid crystalline polymer network is formed using a process comprising one step that comprises polymerizing a mixture of components with linear or lathe-shaped molecules terminated with two or more crosslinking groups in the presence of one or more non-polymerizable liquid crystalline components, wherein
the linear or lathe-shaped molecules terminated with two or more crosslinking groups comprise flexible spacers connecting chromophoric molecular cores to each of the crosslinking groups,
the components with linear or lathe-shaped molecules terminated with two or more crosslinking groups make up between twenty and forty percent of said mixture, and
at least two of the components with linear or lathe-shaped molecules have the same chromophoric core and each of these components make up ten percent or less of said mixture, and
wherein one or more subsequent steps in forming the interconnecting liquid crystalline polymer network are removal of the one or more non-polymerizable liquid crystalline components from the polymerized mixture and then replacing the one or more non-polymerizable liquid crystalline components with a polymerizable material.

2. The photovoltaic device of claim 1 wherein at least one of the chromophoric molecular cores is electron accepting.

3. The photovoltaic device of claim 2 wherein the one or more non-polymerizable liquid crystalline components are electron donating.

4. The photovoltaic device of claim 1 wherein at least one of the chromophoric molecular cores is electron donating.

5. The photovoltaic device of claim 4 wherein the one or more non-polymerizable liquid crystalline components are electron accepting.

6. The photovoltaic device of claim 1 wherein the photovoltaic device comprises a reflector.

7. The photovoltaic device of claim 1 wherein the photovoltaic device is built up on a substrate.

8. The photovoltaic device of claim 7 wherein the substrate is transparent.

9. The photovoltaic device of claim 7 wherein the substrate is glass.

10. The photovoltaic device of claim 7 wherein the substrate is plastic.

11. The photovoltaic device of claim 1 wherein the polymerizable mixture used to form the interconnecting liquid crystalline polymer network is solvent cast on an anode that was previously coated onto a substrate.

12. The photovoltaic device of claim 1 wherein the polymerizable mixture used to form the interconnecting liquid crystalline polymer network is solvent cast on a cathode that was previously coated onto a substrate.

13. The photovoltaic device of claim 1 wherein one or more of the one or more non-polymerizable liquid crystalline components have crystal to nematic phase transitions.

14. The photovoltaic device of claim 1 wherein the interconnecting liquid crystalline polymer network has nematic liquid crystalline order.

15. The photovoltaic device of claim 1 wherein at least one of the components with linear or lathe-shaped molecules terminated with two or more crosslinking groups has a crystal to nematic phase transition.

16. The photovoltaic device of claim 1 wherein at least one of the flexible spacers connecting chromophoric molecular cores to each of the crosslinking groups is a n-alkyl or branched alkyl group.

17. The photovoltaic device of claim 16 wherein at least one of the at least one of the flexible spacers that is a linear or branched alkyl group has at least one of its methylene groups replaced by a an oxygen, sulfur atom, carboxylate group, or carbonato group.

18. The photovoltaic device of claim 1 wherein the two or more crosslinking groups is selected from the group consisting of methacrylato, vinyloxy, phthalimido, acrylato, and 1,4-pentadien-3-yl groups.

19. The photovoltaic device of claim 1 wherein the polymerizable material that replaces the one or more non-polymerizable liquid crystalline components contains one or more materials that comprise chromophoric cores.

20. The photovoltaic device of claim 19 wherein at least one of the chromophoric cores is electron accepting.

21-36. (canceled)
